(19) United States
(12) Patent Application Publication
(10) Pub. No.: US 2011/0108112 A1
(43) Pub. Date: May 12, 2011

(54) DEVICE FOR TRACKING LOCATION OF SUN

(76) Inventors: Jin Woo Hong, Gyeonggi-do (KR); Hee Joon Lee, Chungcheongbuk-do (KR)

(21) Appl. No.: 12/865,716

(22) PCT Filed: Feb. 2, 2009
(86) PCT No.: PCT/KR2009/000502

§ 371 Date: Dec. 14, 2010

(30) Foreign Application Priority Data
Jan. 31, 2008 (KR) 1020080010305
Jun. 11, 2008 (KR) 1020080054653
Jul. 9, 2008 (KR) 1020080066506

(51) Int. Cl. H01L 31/0203; H01L 31/02

(52) U.S. Cl. 136/259; 136/252

(57) ABSTRACT

A solar tracking system, including: a horizontal support; a panel frame connected to the horizontal support such that the panel frame can be tilted forwards and backwards, with a solar battery installed on the panel frame; a support unit connected both to the horizontal support and to the panel frame such that the support unit in cooperation with the horizontal support and the panel frame forms a triangular arrangement, wherein the support unit is slidably connected to either the horizontal support or the panel frame such that the support unit can slide relative to either the horizontal support or to the panel frame, thus tilting the panel frame forwards and backwards according to variations in a slidable position thereof; and a drive unit for sliding the support unit relative to the horizontal support or the panel frame. The solar tracking system realizes a simple, stable support structure and allows the solar battery panel to track the position of the sun with a low amount of power.

### TECHNICAL FIELD

The present invention relates, in general, to solar tracking systems and, more particularly, to a solar tracking system for tracking the position of the sun according to variation in the solar azimuth angle or the solar altitude.

### BACKGROUND ART

Generally, solar energy generating systems use solar batteries, which absorb solar rays and convert the solar light energy into electric energy. The solar batteries are typically used in a state in which the batteries are installed in mounting units having a variety of structures (hereinbelow, the assembly comprising the solar batteries and a mounting unit assembled with the solar batteries will be referred to a “solar battery panel”).

The solar energy generating systems are typically classified into two types: a uniaxial system and a biaxial system, depending on the solar tracking methods.

A uniaxial solar tracking system is configured such that the solar battery panel can be tilted in a direction from east to west according to variations in the solar azimuth angle. The uniaxial solar tracking system does not track the solar altitude, so that the uniaxial solar tracking system has one rotating shaft, thus having a simple construction and being easily installed in the form of a group, and therefore is widely used in combination with solar energy generating systems. Further, the uniaxial solar tracking system can be easily handled and managed compared to the biaxial system. However, the uniaxial solar tracking system is problematic in that it collects a low amount of solar energy.

On the contrary, the biaxial solar tracking system is configured such that the solar battery panel can be tilted in a direction from east to west so as to track variations in the solar azimuth angle and can be tilted upwards and downwards so as to track variations in the solar altitude. However, the biaxial solar tracking system is problematic in that it requires high operational precision that can precisely track the movement of the sun, so that it is difficult to handle or manage the biaxial system and it requires high management cost.

The conventional solar tracking systems including the above-mentioned uniaxial and biaxial systems use a drive unit for moving (tilting) the solar battery panel leftwards, rightwards, upwards and downwards according to both variations in the solar azimuth angle and variations in the solar altitude. In the conventional solar tracking system, the drive unit tilts the solar battery panel using a motor and gears driven by the motor or using hydraulic pressure.

However, the conventional solar tracking systems are problematic as follows. The problem of a solar tracking system using hydraulic pressure is caused by the complex drive unit. The system using a motor-driven mechanism is problematic in that the drive unit for tilting the solar battery panel is located in the center of where the solar battery panel is tilted, so that it is difficult to stably support the large-scaled solar battery panel when the solar battery panel is tilted.

### DISCLOSURE

### Technical Problem

The present invention has been made keeping in mind the above problems occurring in the related art, and is intended to provide a solar tracking system, which uses the principle of the lever and can easily, reliably drive a solar battery panel using a simple structure and a relatively small amount of power.

The present invention is also intended to provide a solar tracking system, which can realize a triangular support structure, thus stably supporting the solar battery panel with such a simple support structure.

Further, the present invention is intended to provide a solar tracking system, which can synchronously drive a plurality of solar battery panels using a simple drive structure.

Further, the present invention is intended to provide a solar tracking system, which can be easily adapted to a uniaxial solar tracking system and a biaxial solar tracking system.

### Technical Solution

The present invention, which can achieve the above-mentioned object and can solve the problems occurring in the related art, may provide a solar tracking system, comprising: a vertical support; a solar battery panel rotatably mounted to an upper end of the vertical support; a drive bar rotatably mounted to an intermediate portion of the support; a guide member rotatably mounted to the upper end of the support and rotated by the drive bar, thus tilting the solar battery panel; and a drive unit rotating the drive bar, wherein the drive bar is connected to the guide member such that the drive bar can be linearly moved along the guide member.

In an embodiment, a panel tilting shaft may be mounted to the upper end of the support such that the panel tilting shaft extends horizontally, and the solar battery panel and the guide member may be mounted to the panel tilting shaft such that the solar battery panel and the guide member can be rotated simultaneously.

The guide member may be provided with a guide rail and the drive bar may be provided with a roller which rolls along the guide rail.

When the solar tracking system is adapted to a uniaxial system, the support, the solar battery panel, the drive bar and the guide member may form a basic set, a plurality of basic sets may be sequentially arranged, and the drive unit may synchronously drive the solar battery panels provided in the plurality of basic sets.

In an embodiment, the drive unit may comprise a drive motor, a drive shaft for transmitting a rotating force of the drive motor to the drive bars of the basic sets, and a power transmission mechanism provided between the drive shaft and the drive bars. Further, the power transmission mechanism may comprise a worm gear provided on a bar rotating shaft of the drive bar.

Here, the drive bar may be driven by a rectilinearly reciprocating mechanism instead of the drive shaft rotating mechanism. In the above state, a rack gear may be provided on the drive shaft and a pinion may be provided on the rotating shaft of the drive bar, thus transmitting the rotating force.

Further, the drive unit may be a drive motor directly installed on the support and rotating the drive bar.

When the solar tracking system is used in a biaxial system, the support may be configured such that it rotates the solar battery panel, the drive bar and the guide member therearound.

The present invention, which can achieve the above-mentioned object and can solve the problems occurring in the related art, may also provide a solar tracking system, comprising: a horizontal support; a panel frame connected to the horizontal support such that the panel frame can be tilted forwards and backwards, with a solar battery installed on the panel frame; a support unit connected both to the horizontal support and to the panel frame such that the support unit in cooperation with the horizontal support and the panel frame forms a triangular arrangement, wherein the support unit is slidably connected to either the horizontal support or the panel frame such that the support unit can slide relative to either the horizontal support or to the panel frame, thus tilting the panel frame forwards and backwards according to variations in a slidable position thereof; and a drive unit for sliding the support unit relative to the horizontal support or the panel frame.

Here, the support unit may be slidably connected to the panel frame at an upper end thereof and may be rotatably connected to the horizontal support at a lower end thereof.

In the above state, the panel frame may be provided with a transversely extending guide frame to which the support unit is slidably connected, and the guide frame may be rotatably connected to the horizontal support at a lower end thereof.

The guide frame may be provided with a guide rail and the support unit may be provided with a roller which is engaged with and rolls along the guide rail.

The drive unit may comprise: a rack provided on the guide frame, a pinion provided on the support unit and engaged with the rack, and a drive motor provided on the support unit and rotating the pinion.

The support unit may be rotatably connected to the panel frame at an upper end thereof and may be slidably connected to the horizontal support at a lower end thereof.

In the above state, the horizontal support may be provided with a transversely extending guide frame to which the support unit is slidably connected, and the panel frame may be rotatably connected to an end of the guide frame.

The guide frame may be provided with a guide rail and the support unit may be provided with a roller which is engaged with and rolls along the guide rail.

The drive unit may comprise: a rack provided on the guide frame, a pinion provided on the support unit and engaged with the rack, and a drive motor provided on the support unit and rotating the pinion.

The support unit may comprise two pairs of parallel support bars, with the pinion located between each pair of support bars, wherein a shaft housing may be connected to the two pairs of support bars, and the shaft housing may be provided with both the drive motor and a drive shaft for transmitting a rotating force of the drive motor to the pinion.

The horizontal support may be rotatably installed on a vertical support using a horizontal rotating mechanism.

The horizontal rotating mechanism may comprise an upper column mounted to the horizontal support and a lower column constituting the vertical support, wherein one of the upper and lower columns is rotatably fitted into a remaining column, and a rotation drive unit is provided between the upper column and the lower column and rotates the upper column relative to the lower column.

The rotation drive unit may comprise: a plurality of protrusions formed on a lower surface of a flange provided in the lower column such that the protrusions are circumferentially spaced apart from each other at regular intervals; and a cam gear mounted to the upper column and engaged with the protrusions such that, when the drive motor is rotated, the cam gear moves in a circumferential direction of the lower column due to relative movement between the cam gear and the protrusions, thus rotating the upper column.

Further, the rotation drive unit may comprise: a plurality of protrusions formed on an upper or lower surface of a flange provided in the upper or lower column such that the protrusions are circumferentially spaced apart from each other at regular intervals; and a cam gear mounted to a remaining column and engaged with the protrusions such that, when the drive motor is rotated, the cam gear moves in a circumferential direction of the lower column due to relative movement between the cam gear and the protrusions, thus rotating the upper column.

Further, the horizontal rotating mechanism may rotatably support the upper structure on the vertical support, and may comprise a rotation drive unit installed between the upper structure and the vertical support and rotating the upper structure relative to the vertical support, wherein the rotation drive unit may comprise: a driven gear formed around the vertical support; and a drive body mounted to the upper structure and having a plurality of engaging rods circumferentially arranged in the drive body and engaged with the driven gear, thus being rotated around the driven gear by a rotating force of the drive motor mounted to the upper structure and thereby rotating the upper structure including the panel frame.

### Effects

The solar tracking system according to the present invention has the following advantages.

The solar tracking system of the present invention is configured such that it can tilt the solar battery panel upwards or downwards, thus easily and reliably driving the solar battery panel using a simple structure and a relatively low amount of power.

In other words, unlike the conventional solar tracking systems in which the drive unit is located in the center from which the solar battery panel is tilted, the present invention is configured such that a drive bar executing a lever action is installed at a location remote from the center of tilting of the solar battery panel and moves the solar battery panel, thus easily tracking the position of the sun by simply changing the construction of the solar tracking system. Due to the principle of the lever, when the solar battery panel is positioned in an almost horizontal state, the drive bar is positioned in the center of tilting of the solar battery panel and most load is concentrated on the support, so that the solar battery panel can be driven by a relatively low amount of power. Particularly, when the solar battery panel is tilted, the drive bar drives the solar battery panel at a location remote from the center from which the solar battery panel is tilted, thus efficiently driving the solar battery panel using low drive power.

Further, in the present invention, the drive unit is directly connected to a portion in which the support unit slides, so that the present invention can minimize drive power loss, thereby efficiently controlling the solar tracking system.

Further, the present invention can realize a triangular support structure in a state in which the solar battery panel is at a tilt, so that the invention can stably and firmly support the solar battery panel.

Further, when the present invention is adapted to a uniaxial solar tracking system, the system can be configured such that a plurality of solar battery panels can be synchronously driven using one drive unit. Thus, the present invention can synchronously drive the plurality of solar battery panels using a simple structure.

Another advantage of the present invention resides in that the invention may be easily adapted to a uniaxial or biaxial solar tracking system.

Further, the present invention is configured such that a cam gear movably engages with a plurality of vertically arranged protrusions, so that the invention can produce stable rotating power and can reduce the space required to install the rotation drive unit.

### BRIEF DESCRIPTION OF DRAWINGS

FIGS. 1 through 9 are views illustrating a solar tracking system according to a first embodiment of the present invention, in which:

FIG. 1 is a perspective view illustrating the entire construction of the solar tracking system;

FIG. 2 is a perspective view illustrating the solar tracking system, from which a solar battery panel has been removed;

FIG. 3 is an exploded perspective view illustrating the solar tracking system, from which the solar battery panel is removed;

FIG. 4 is a perspective view illustrating important parts of the solar tracking system, from which the solar battery panel is removed;

FIG. 5 is a front view illustrating the important parts of the solar tracking system, from which the solar battery panel is removed;

FIG. 6 is a side view illustrating the solar tracking system, from which the solar battery panel is removed; and

FIG. 7 through FIG. 9 are side views illustrating the operation of the solar tracking system;

FIG. 10 through FIG. 18 are views illustrating a solar tracking system according to a second embodiment of the present invention, in which:

FIG. 10 is a perspective view illustrating the entire construction of the solar tracking system;

FIG. 11 is a rear perspective view illustrating the entire construction of the solar tracking system;

FIG. 12 is a right side view of the solar tracking system;

FIG. 13 is a left side view of the solar tracking system;

FIG. 14 is a perspective view illustrating the solar tracking system, from which a solar battery panel is removed;

FIG. 15 is a rear perspective view illustrating the solar tracking system, from which the solar battery panel is removed;

FIG. 16 is a rear exploded perspective view illustrating the solar tracking system, from which the solar battery panel is removed;

FIG. 17 is a front view illustrating the solar tracking system, from which the solar battery panel is removed; and

FIG. 18 is a rear view illustrating the solar tracking system, from which the solar battery panel is removed;

FIG. 19 through FIG. 21 are views illustrating a solar tracking system according to a third embodiment of the present invention, in which:

FIG. 19 is a side view;

FIG. 20 is a rear view; and

FIG. 21 is a rear perspective view;

FIG. 22 and FIG. 23 are a plan view and a top perspective view illustrating the solar tracking system according to the third embodiment of the present invention, in which:

FIG. 22 is a view illustrating exploded parts in detail; and

FIG. 23 is a view illustrating important parts, from which a pinion cap is removed;

FIG. 24 is an exploded perspective view illustrating a solar tracking system according to the third embodiment of the present invention;

FIG. 25 through FIG. 30 are views illustrating a solar tracking system according to a fourth embodiment of the present invention, in which:

FIG. 25 is a side view;

FIG. 26 is a front perspective view;

FIG. 9 is a rear perspective view;

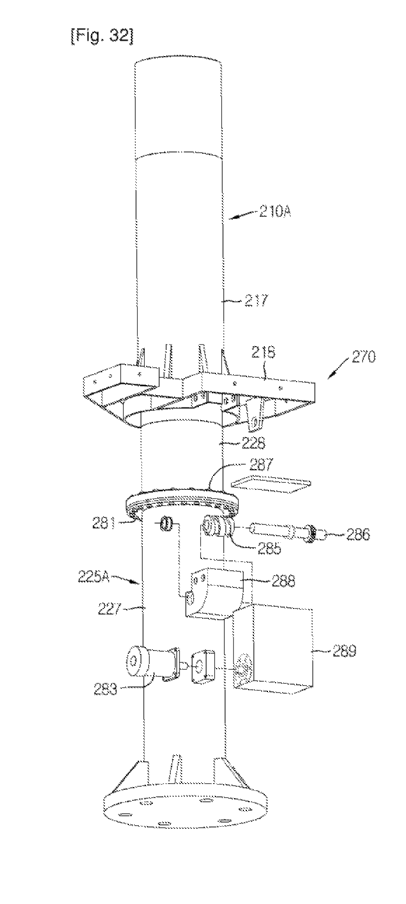

FIG. 28 is a rear view;

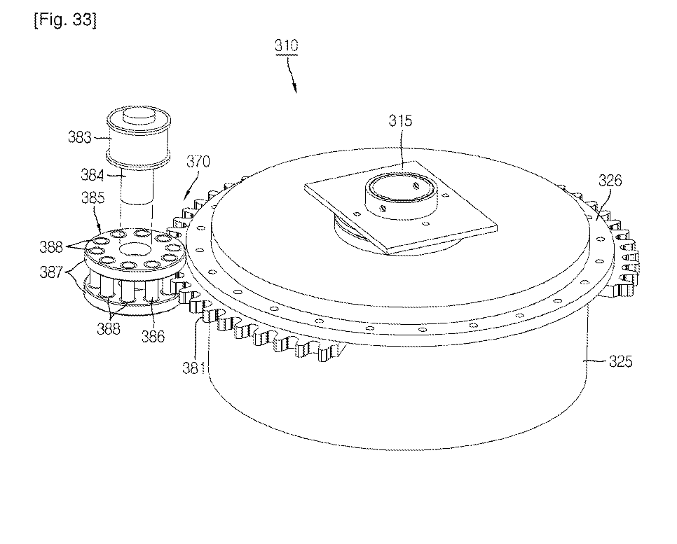

FIG. 29 is a plan view; and

FIG. 30 is an exploded perspective view;

FIG. 31 and FIG. 32 are views illustrating a solar tracking system according to a fifth embodiment of the present invention, in which:

FIG. 31 is a perspective view illustrating the entire construction of the solar tracking system; and

FIG. 32 is an exploded perspective view illustrating important parts; and

FIG. 33 is a perspective view illustrating a horizontal rotating mechanism according to another embodiment of the present invention.

### BEST MODE

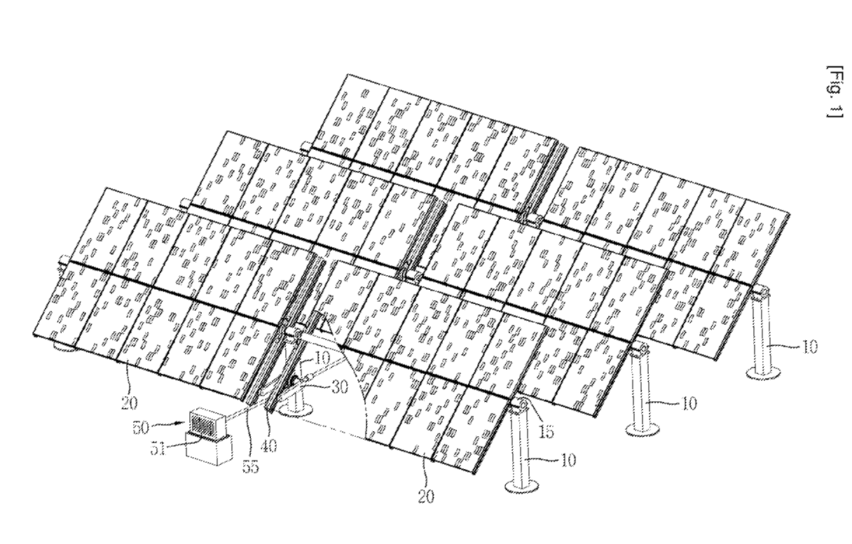

As shown in FIG. 1, a solar tracking system according to an embodiment of the present invention comprises a vertical support 10, a solar battery panel 20 rotatably mounted to an upper end of the vertical support 10, a drive bar 30 rotatably connected to the support 10, a guide member 40 rotatably mounted to the upper end of the support 10 or mounted to the solar battery panel and rotated by the drive bar 30, thus tilting the solar battery panel 20, and a drive unit 50 rotating the drive bar 30.

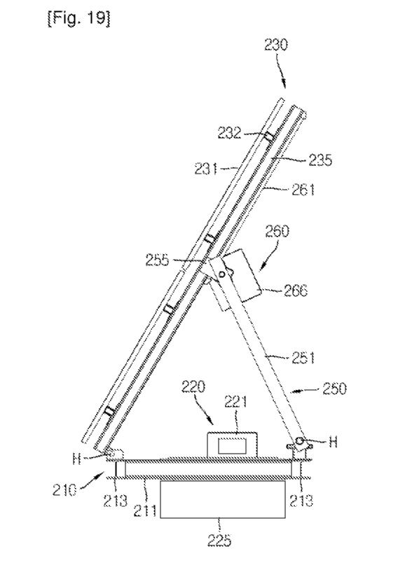

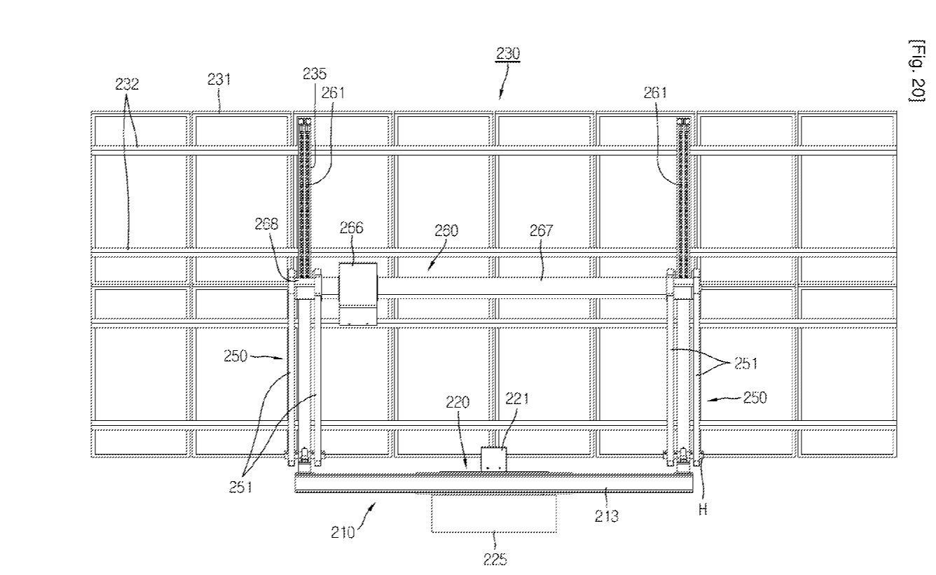

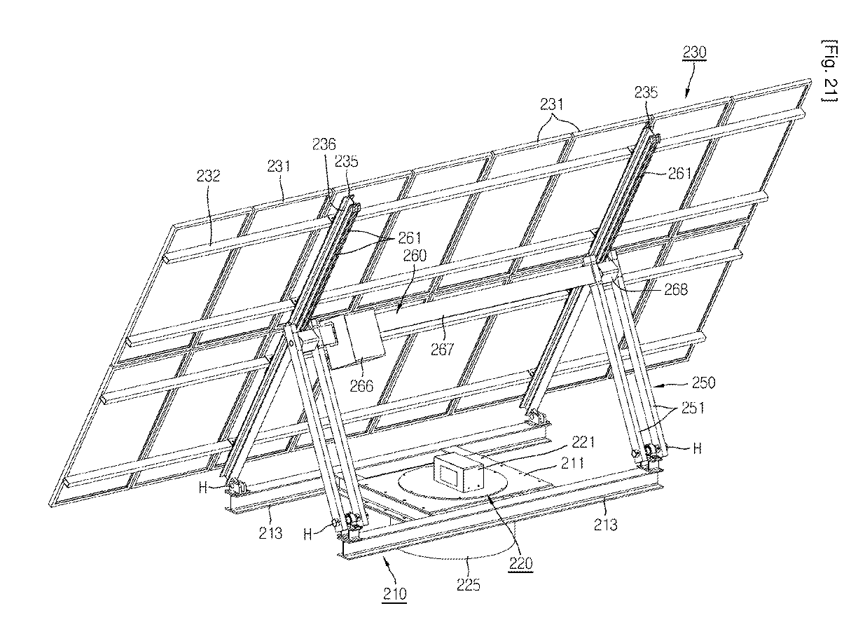

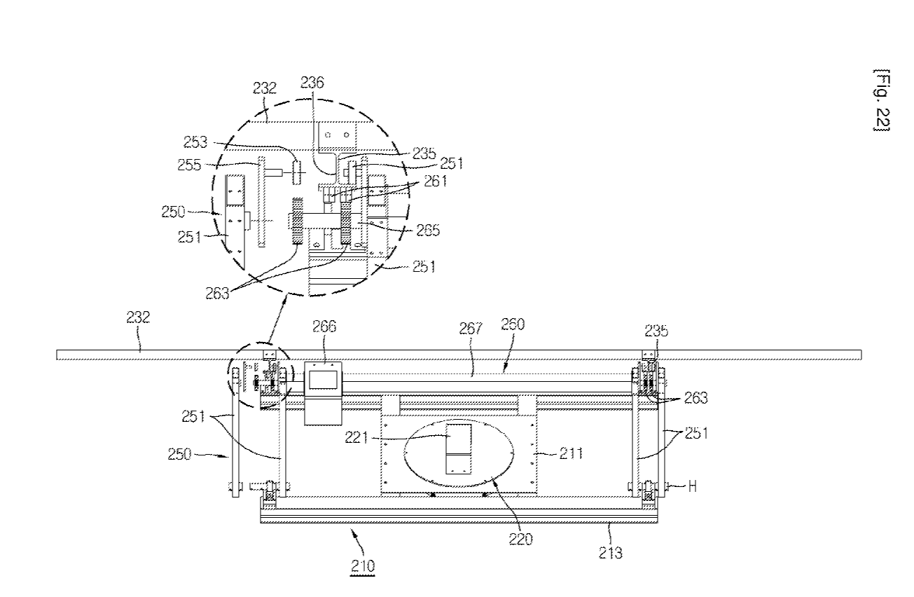

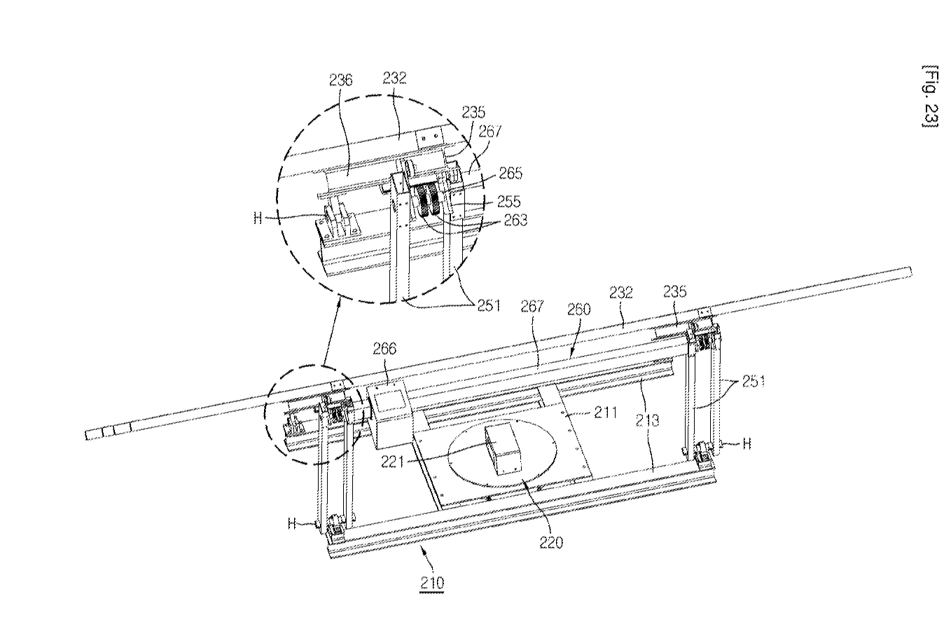

As shown in FIG. 19, a solar tracking system according to another embodiment of the present invention comprises a horizontal support 210, a panel frame 230 and a support unit 250, which are arranged in a triangular arrangement, and a drive unit 260, which moves the support unit 250 relative to the panel frame 230.

### Mode for Invention

Hereinbelow, preferred embodiments of the present invention will be described in detail with reference to the accompanying drawings.

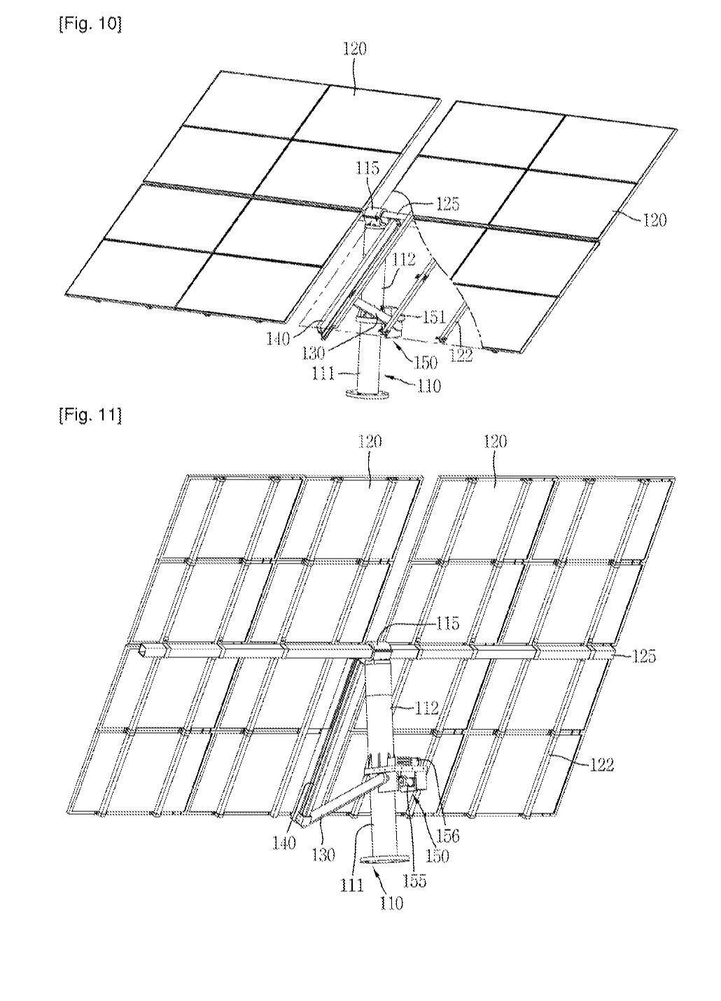

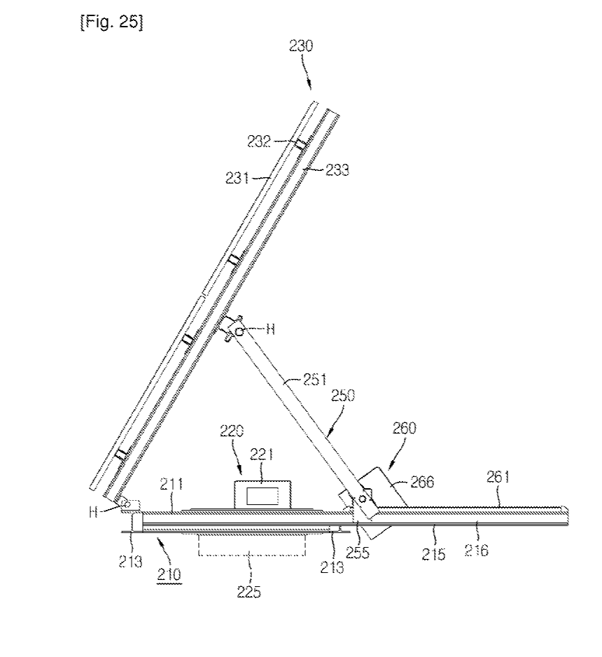

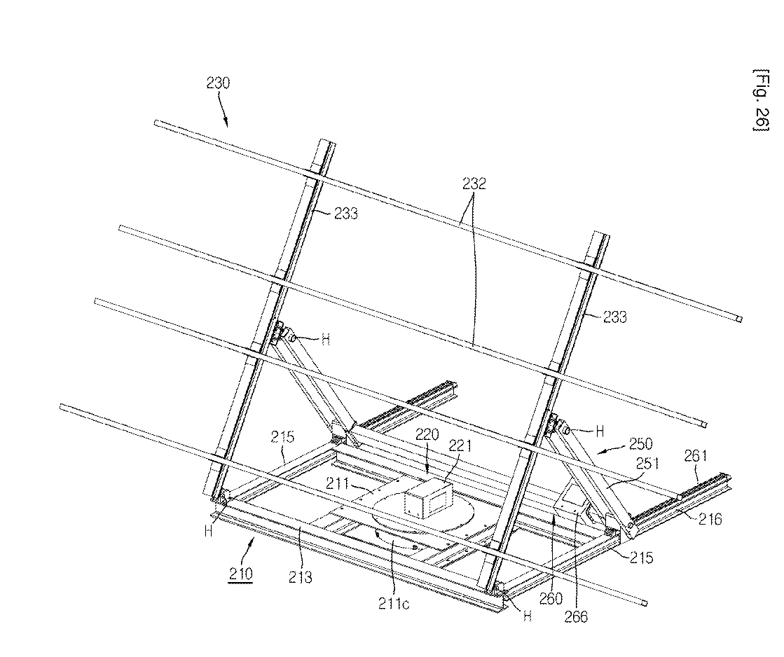

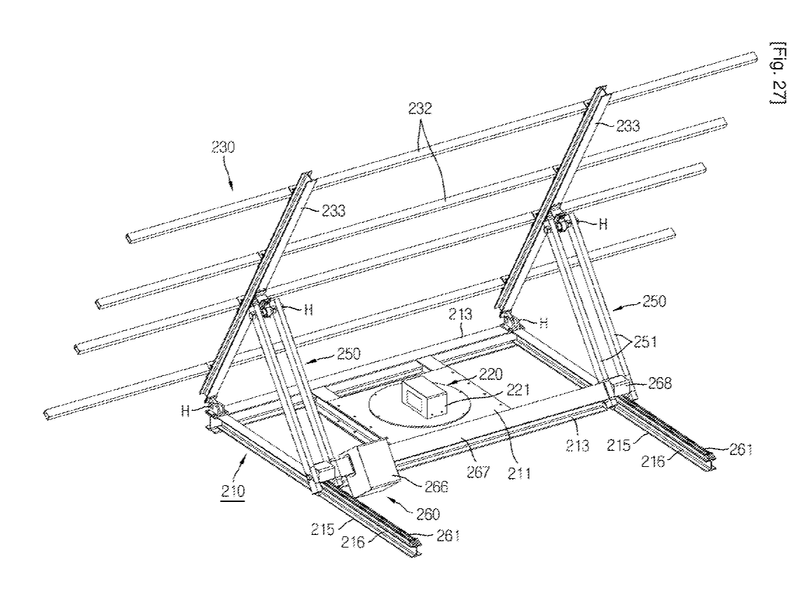

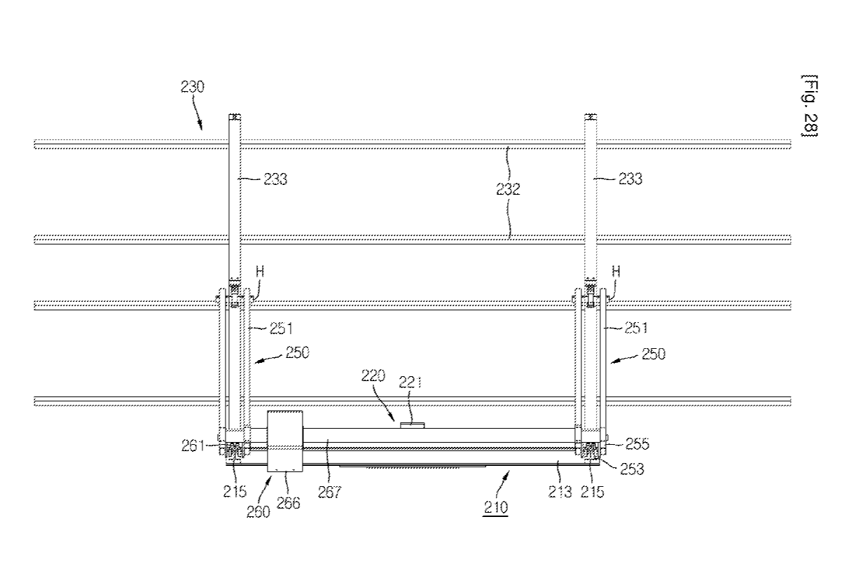

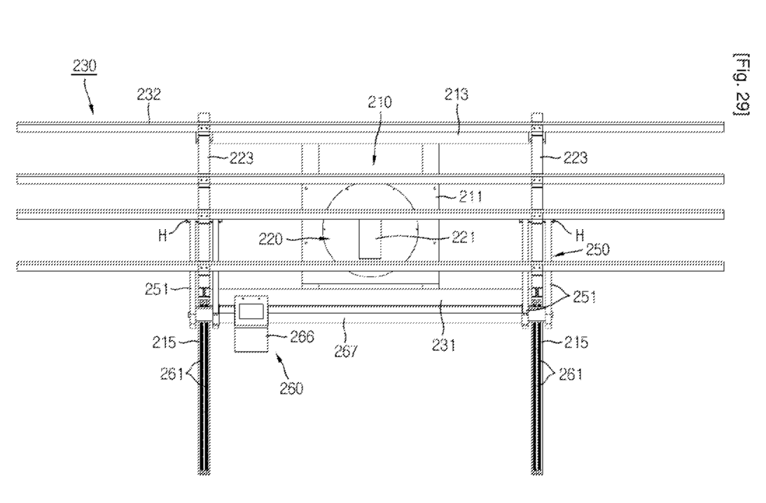

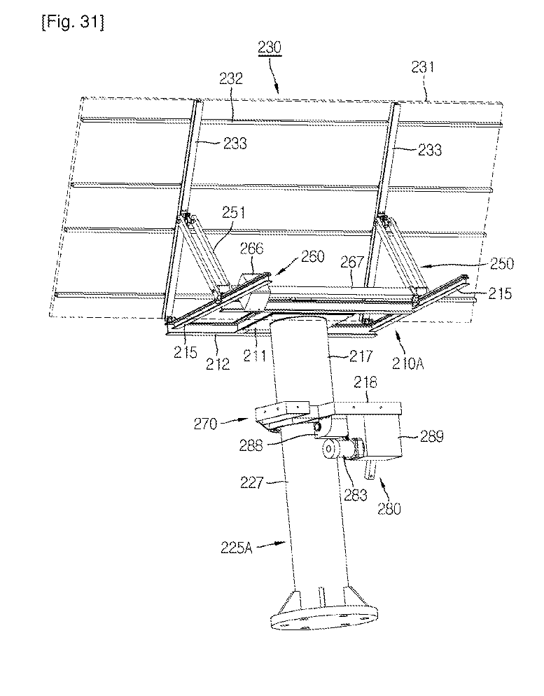

In the following description, five embodiments of the present invention will be described. That is, a uniaxial solar tracking system according to a first embodiment of the present invention will be described with reference to FIGS. 1 through 9. A biaxial solar tracking system according to a second embodiment of the present invention will be described with reference to FIGS. 10 through 18. Further, a third embodiment of the present invention will be described with reference to FIGS. 19 through 24. A fifth embodiment of the present invention will be described with reference to FIGS. 25 through 30. A fifth embodiment of the present invention will be described with reference to FIGS. 31 through 32. Another embodiment of a horizontal rotating mechanism according to the present invention will be described with reference to FIG. 33.

At first, the first embodiment in which the solar tracking system of the present invention is used in a uniaxial solar energy generating system will be described hereinbelow with reference to FIGS. 1 through 9.

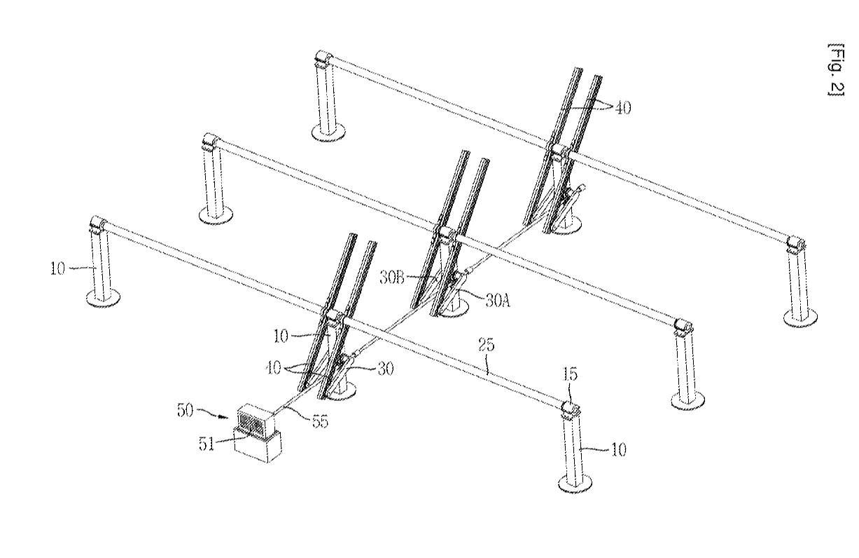

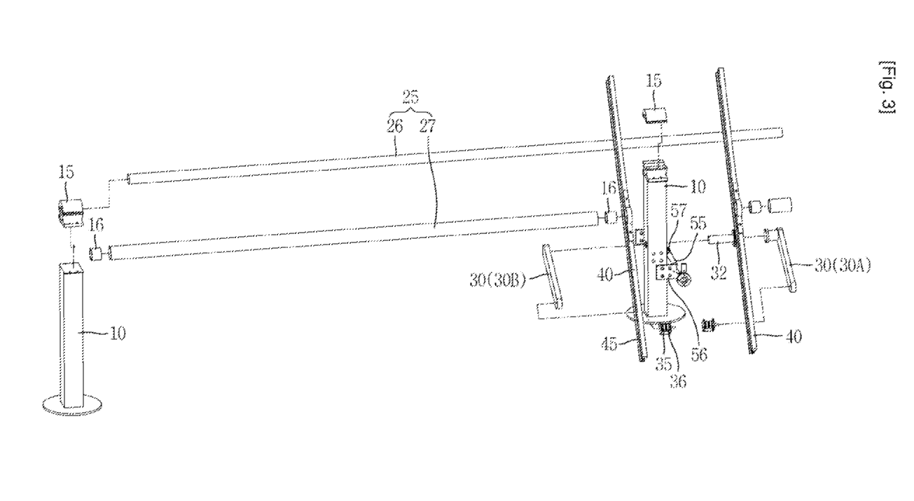

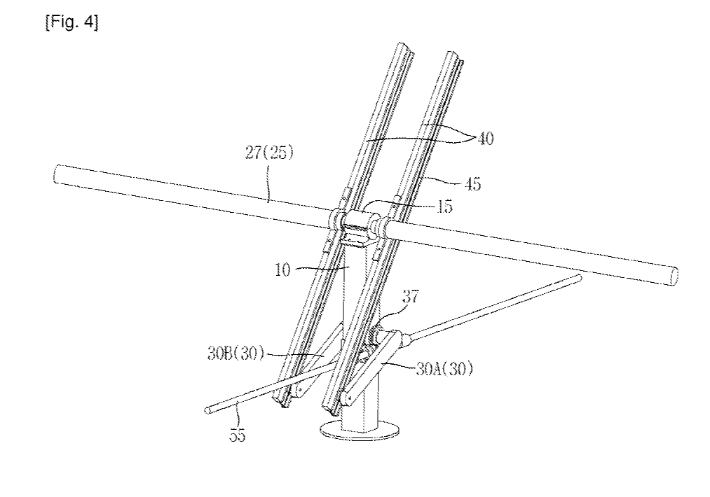

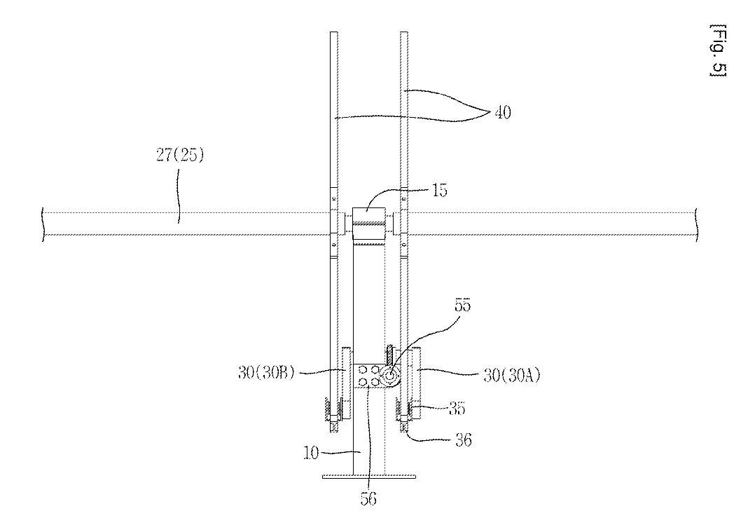

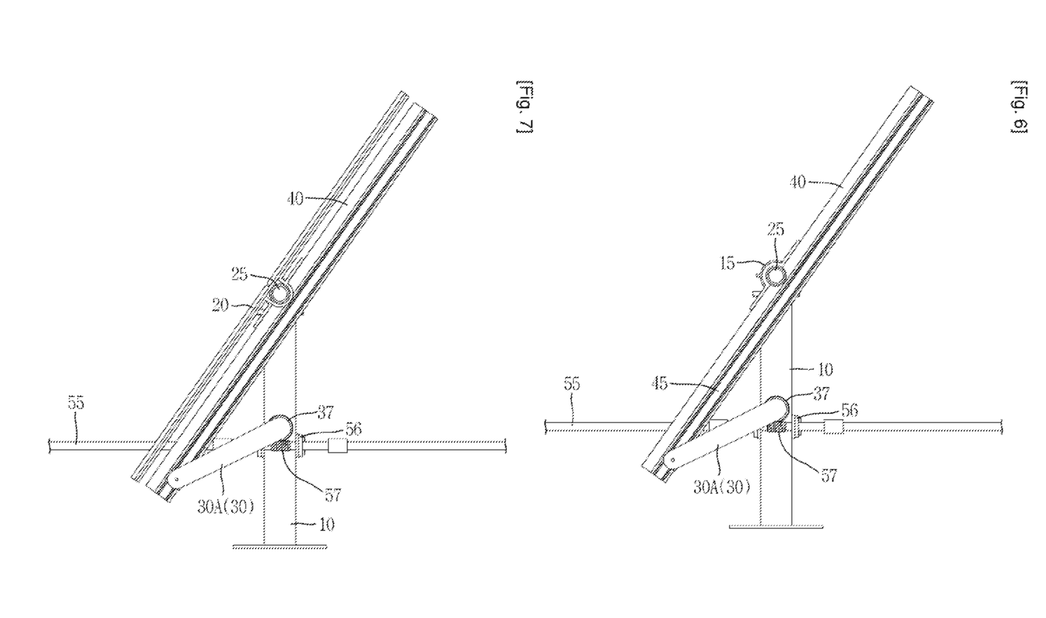

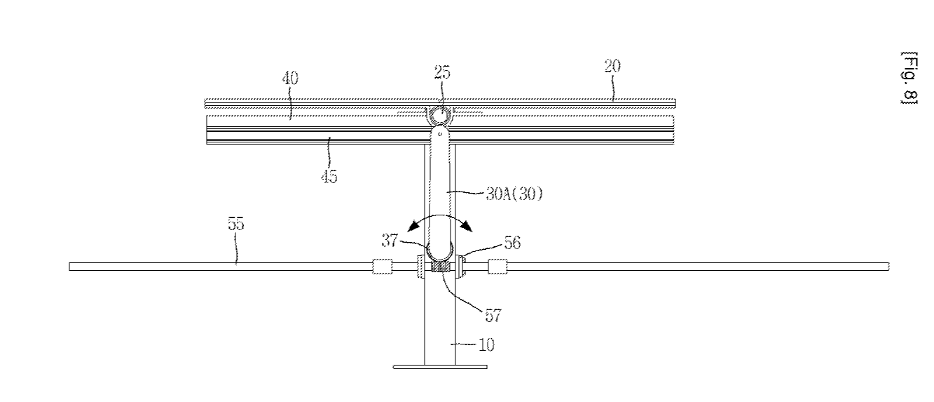

FIG. 1 is a perspective view illustrating the overall construction of the solar tracking system. FIGS. 2 through 6 are views of the solar tracking system, from which a solar battery panel is removed, in which FIG. 2 is a perspective view, FIG. 3 is an exploded perspective view, FIG. 4 is a perspective view of important parts, FIG. 5 is a front view of the important parts, and FIG. 6 is a side view. FIGS. 7 through 9 are side views illustrating the operation of the solar tracking system.

In the drawings, FIGS. 1 through 9 showing the embodiment, a plurality of sets of solar battery panels 20 are sequentially arranged. However, it should be understood that one set including one solar battery panel 20 may be independently installed.

In the following description, the embodiment will be described for a structure capable of synchronously actuating the plurality of sets of solar battery panels 20.

As shown in FIG. 1, the solar tracking system according to the first embodiment of the present invention comprises a vertical support 10, a solar battery panel 20 rotatably mounted to an upper end of the vertical support 10, a drive bar 30 rotatably mounted to the support 10, a guide member 40 rotatably mounted to the upper end of the support 10 or mounted to the solar battery panel and rotated by the drive bar 30, thus tilting the solar battery panel 20, and a drive unit 50 rotating the drive bar 30. Here, the support 10, the solar battery panel 20, the drive bar 30 and the guide member 40 constitute one basic set. In the embodiment of the present invention, several basic sets each having the above-mentioned construction are sequentially arranged, as shown in the drawings. Further, the drive unit 50 is configured to synchronously drive the solar battery panels 20 provided in the plurality of basic sets.

Hereinbelow, important parts of the solar tracking system according to the first embodiment of the present invention will be described.

At first, the support 10 comprises a plurality of supports (in the drawings, three supports per row) supporting the solar battery panels 20 at opposite ends of the panels 20. A panel tilting shaft 25 horizontally extends between the upper ends of opposite supports 10.

It is preferred that the panel tilting shaft 25 be rotatably supported by hubs 25 at the upper end of the opposite supports 10. The panel tilting shaft 25 may be integrated with the solar battery panel 20. Alternatively, as shown in the drawings, the panel tilting shaft 25 may be provided separately from the solar battery panel 20. In the above state, the solar battery panel 20 may be combined with the panel tilting shaft 25 using guide members 40 such that the panel 20 can be tilted along with the guide members 40 by the shaft 25.

As shown in FIG. 3, the panel tilting shaft 25 may be configured to have a biaxial structure, which comprises an inner core shaft 26 and an outer rotatable shell shaft 27. In the above state, the core shaft 26 is fixed to the upper ends of the supports 10 using the hubs 15, while the rotatable shell shaft 27 is rotatably fitted over the core shaft 26. Of course, a bearing 16 or a bushing may be installed between the core shaft 26 and the rotatable shell shaft 27 such that the rotatable shell shaft 27 can be reliably rotated.

The solar battery panel 20 is provided with solar batteries for absorbing solar rays and converting the solar light energy into electric energy. As shown in FIG. 1, the solar batteries are arranged on the panel such that the batteries absorb the solar rays. Here, the structure of the solar battery panel 20 is not limited to the flat panel structure shown in the drawings, but may be changed to another structure capable of absorbing the solar rays using a reflective panel as desired.

When two solar battery panels 20 are arranged in each row at opposite locations based on the drive unit 50, two drive bars 30 are mounted to each center support 10, as shown in FIG. 2.

In the embodiment, the two drive bars 30 are configured such that the first drive bar 30A is directly driven by the drive unit 50 and the second drive bar 30B is connected to the first drive bar 30A by a bar rotating shaft 32, as shown in FIG. 3, so that the second drive bar 30B can be driven by the first drive bar 30A. Of course, it should be understood that the second drive bar 30B may be directly connected to the drive unit 50 such that the drive bar 30B can be directly driven by the drive unit 50.

The drive bar 30 has a long bar structure. The first end of the drive bar 30 is connected to the bar rotating shaft 32, which passes through the support 10, such that the drive bar 30 can be rotated around a predetermined point. The second end of the drive bar 30 is movably connected to a guide member 40 such that the drive bar 30 can slide relative to the guide member 40.

The relative movable connection between the drive bar 30 and the guide member 40 is realized by connecting the drive bar 30 to the guide member 40 such that the drive bar 30 can linearly move along the guide member 40.

Due to the above-mentioned structure, when the drive bar 30 is rotated by the drive unit 50, the first end of the drive bar 30 is rotated around the bar rotating shaft 32, while the second end of the drive bar 30 slides along the side surface of the guide member 40, so that the guide member 40 can be rotated around the panel tilting shaft 25.

Further, the guide member 40 is provided with a guide rail 45 along at least one side surface thereof such that the second end of the drive bar 30 can be movably engaged with the guide rail 45 and can be linearly moved along the guide rail 45.

In the drawings showing the first embodiment, one guide rail 45 is formed along each side surface of the guide member 40 and the drive bar 30 is engaged with the guide rails 45. Further, the guide rail 45 is configured in the form of a longitudinal groove structure and the drive bar 30 is provided with a roller 35, which is movably engaged with the guide rail 45 and rolls along the guide rail 45.

In the above state, it is preferred that the roller 35 be movably installed in the guide rail 45 such that diametrically opposite ends of the rim of the roller 35 come into contact with opposite inner surfaces (upper and lower inner surfaces) of the guide rail 45. The above-mentioned engagement of the roller 35 in the guide rail 45 minimizes clearance between the roller and the guide rail when the roller 35 is installed in the guide rail 45, thus realizing the reliable rolling of the roller along the guide rail.

In the present invention, it is preferred that two rollers 35 be provided on each drive bar 30 such that the two rollers 35 are engaged with opposite side surfaces of the guide member 40. Here, it is preferred that the two rollers 35 be installed in a U-shaped roller bracket 36 (see FIG. 3) such that the two rollers 35 can be rotatable. In the above state, the roller bracket 36 is installed in the end of the drive bar 30.

In the drawings showing the embodiment, the guide member 40 is configured to form a longitudinal bar structure formed separately from the solar battery panel 20. However, it should be understood that the guide member 40 may be directly combined with the solar battery panel 20 such that the guide member 40 can be rotated along with the solar battery panel 20.

As shown in FIG. 2, the drive unit 50 comprises a drive motor 50 located in a desired space, a drive shaft 55 transmitting the rotating force of the drive motor 50 to the drive bars 30A of respective sets, and a power transmission mechanism provided between the drive shaft 55 and the drive bars 30.

Here, the power transmission mechanism preferably comprises worm gears 37 and 57 (see FIG. 6) which are provided to the drive shaft 55 and the bar rotating shaft 32 of the drive bar 30, respectively. However, it should be understood that the construction of the power transmission mechanism is not limited to the above-mentioned construction, but may be freely selected from a variety of conventional constructions of the power transmission mechanism which can transmit the rotating force of the drive shaft 55 to the drive bar 30.

In FIG. 3, reference numeral 56 denotes a shaft bracket supporting the drive shaft 55.

Further, although it is not shown in the accompanying drawings, the drive unit 50 may be configured in an individual drive type unit instead of the synchronous drive type unit. In the above state, one drive motor is provided for each support 10 so as to drive the drive bar 30 of each support 10.

The embodiment shown in FIGS. 1 through 9 has the structure in which the drive shaft is rotated using one motor. However, the solar tracking system of the present invention may be configured such that the drive shaft 55 can be rectilinearly reciprocated by a power source, such as a motor (actuator), and can rotate the drive bars 30. In the above state, the drive shaft 55 is provided with a rack gear and the drive bars 30 are provided with respective pinions for realizing desired power transmission from the drive shaft to the drive bars.

In the above-mentioned solar tracking system according to the first embodiment of the present invention, when the drive shaft 55 of the drive unit 50 is rotated, the drive bars 30 can be rotated around respective bar rotating shafts 32, as shown in FIG. 7 through FIG. 9. In the above state, the guide members 40, which are movably connected to the drive bars 30 so as to be relatively movable, are pushed upwards or pulled downwards in conjunction with the rotation of the drive bars 30, thus being rotated around the panel tilting shafts 25.

When the panel tilting shaft 25 is rotated, the solar battery panel 20 combined with the panel tilting shaft 25 is rotated in the same direction, thus tracking the variable position of the sun.

The above-mentioned solar tracking system of the present invention realizes the lever action of the drive bar 30 which can easily and reliably tilt the solar battery panel using a small amount of power.

Described in detail, when it is required to tilt the solar battery panel 20 in the state shown in FIG. 7 and FIG. 9, the drive bar 30 pushes the solar battery panel upwards at a location remote from the center of the solar battery panel, so that, unlike the conventional drive mechanism in which the solar battery panel is directly tilted from the center of the panel, the present invention can easily tilt the solar battery panel using a relatively low amount of power.

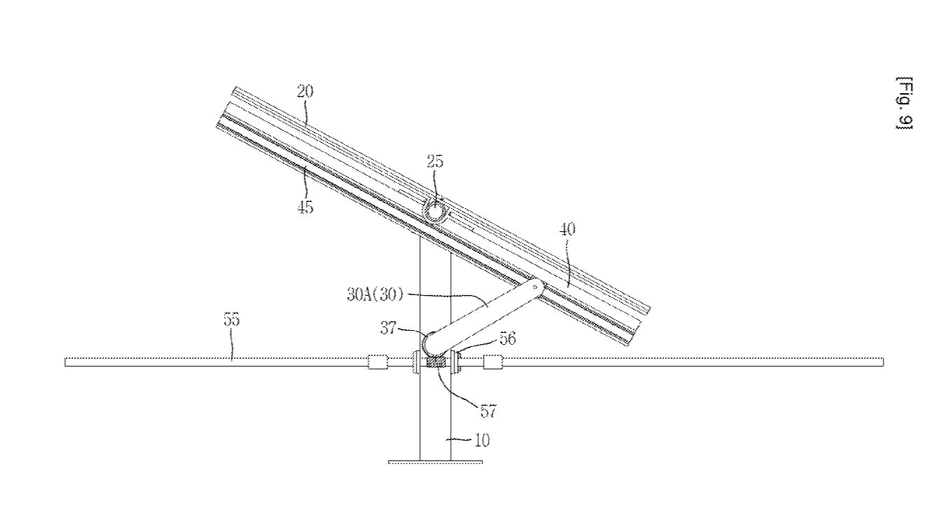

Further, when the solar battery panel is in an almost horizontal position as shown in FIG. 8, the weight of the solar battery panel is concentrated on the supports 10, so that, even in the above state, the drive bar 30 can easily tilt the solar battery panel by pushing or pulling the solar battery panel using a low amount of power.

Thus, in the present invention using the drive bar 30 executing the lever action, when it is required to use high power to rotate the solar battery panel, the drive bar pushes the solar battery panel at a location remote from the center of the panel, where it is tilted from, using the principal of the lever. However, when the solar battery panel is in a balanced position as shown in FIG. 8 and can be tilted using a low amount of power, the drive bar can push the panel at a location near the center of tilting. Therefore, the present invention can efficiently use the power to drive the solar battery panel.

When the solar battery panel is in the tilted state in which the panel is tilted to a side as shown in FIG. 7 and FIG. 9, the drive bar 30 in cooperation with the support 10 and the guide member 40 supports the solar battery panel while forming a triangular structure. Further, when the solar battery panel 20 is in a horizontal position, the panel tilting shaft 25 and the drive bar 30 form a T-shaped structure. In the above state, the rollers 35 installed in opposite side surfaces of the guide member 40 function as a brake, and stop the rotation of both the guide member 40 and the solar battery panel 20, thus realizing a stable support structure for solar battery panels.

Hereinbelow, a second embodiment, in which the solar tracking system of the present invention is adapted to a biaxial system, will be described with reference to FIGS. 10 through 18.

Here, unlike the first embodiment in which the uniaxial solar tracking system can track the position of the sun according to the variation in the solar azimuth angle, the solar tracking system having the biaxial structure according to the second embodiment is configured such that it can track the position of the sun according both to the variation in the solar azimuth angle and the variation in the solar altitude.

The solar tracking system having the biaxial structure according to the present invention will be described hereinbelow with reference to the accompanying drawings.

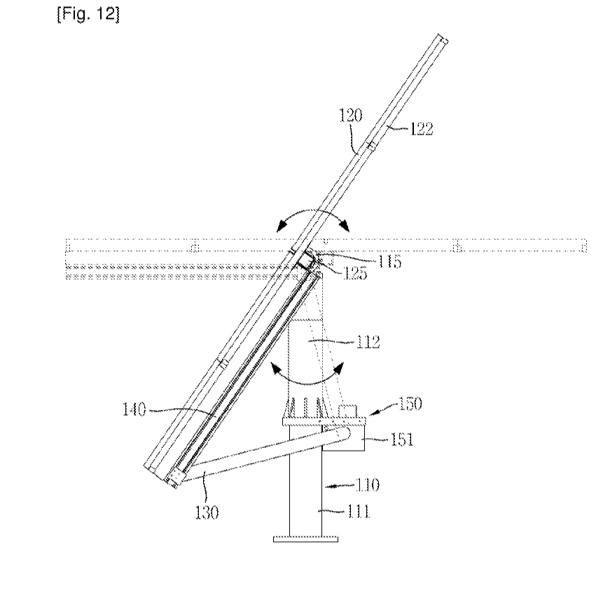

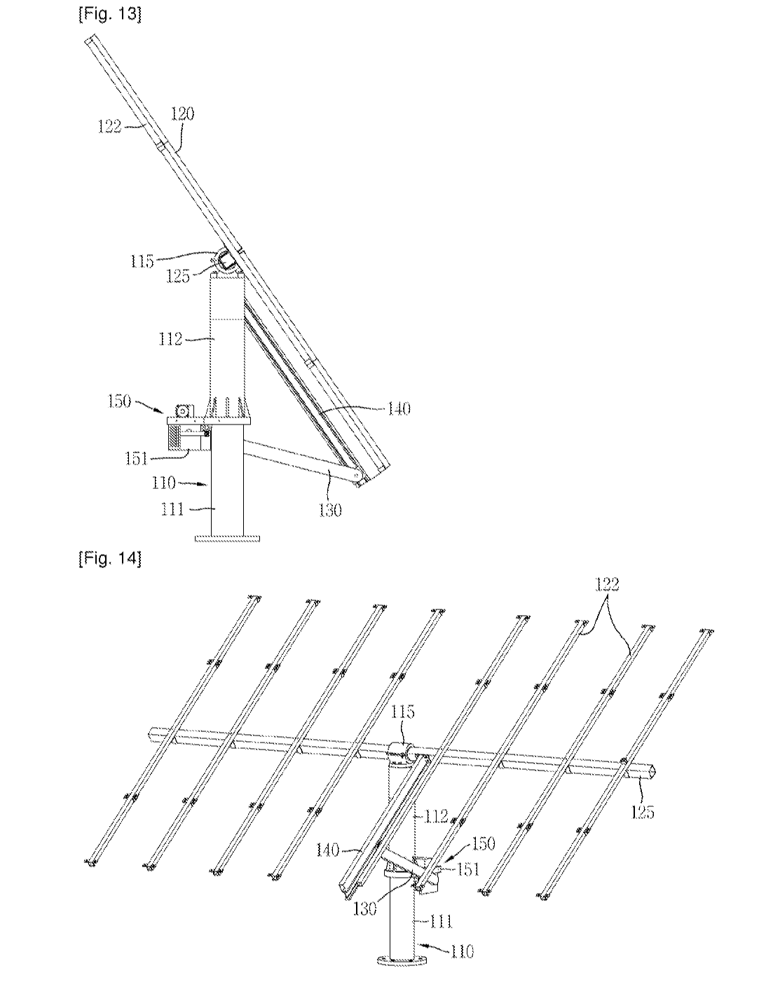

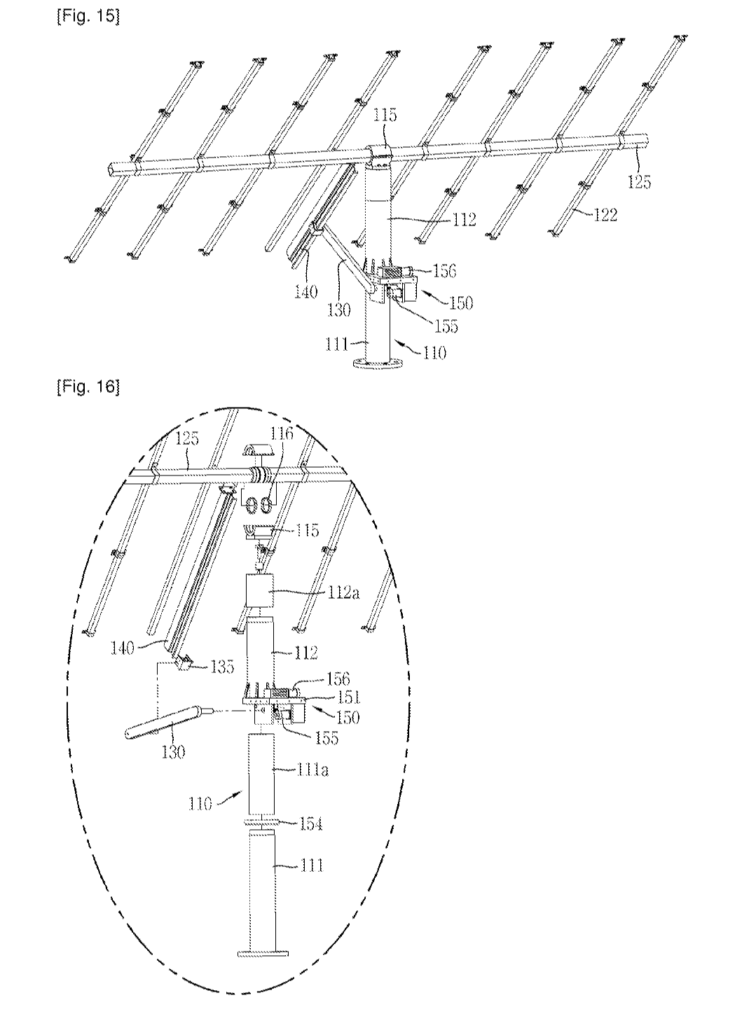

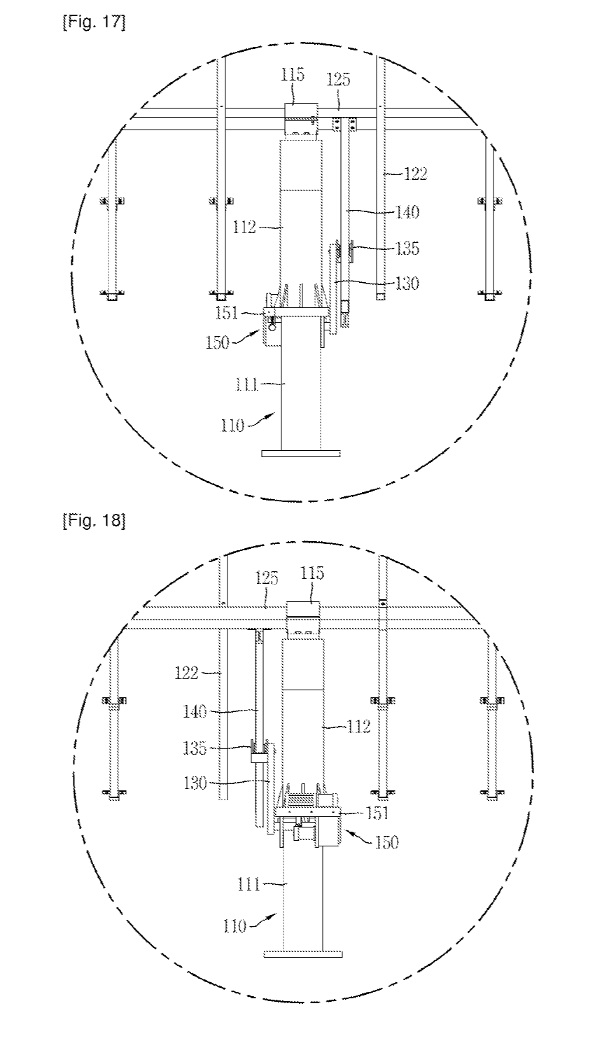

FIGS. 10 through 13 are views illustrating the overall construction of the solar tracking system according to the second embodiment of the present invention, in which: FIG. 10 is a perspective view, FIG. 11 is a rear perspective view, FIG. 12 is a right side view and FIG. 13 is a left side view. FIGS. 14 through 18 are views illustrating the solar tracking system, from which the solar battery panel is removed, in which: FIG. 14 is a perspective view, FIG. 15 is a rear perspective view, FIG. 16 is a rear exploded perspective view, FIG. 17 is a front view and FIG. 18 is a rear view.

As shown in the drawings, a panel tilting shaft 125 is horizontally mounted to one support 110 and a plurality of solar battery panels 120 are supported on the panel tilting shaft 125.

The panel tilting shaft 125 is rotatably mounted to the upper end of the support 110 using a hub 115 having a bearing 116. The solar battery panels 120 are supported on a plurality of panel support bars 122 which are installed on the panel tilting shaft 125 at regular intervals, as shown in FIG. 14.

Particularly, a guide member 140 having a structure similar to that of the guide member 40 according to the first embodiment is installed on the panel tilting shaft 125 such that the guide member 140 extends parallel to the panel support bars 122. A drive bar 130 is rotatably mounted to the support 110 and is slidably coupled to the guide member 140.

Here, the detailed construction of the guide member 140 and the connection structure of the drive bar 130 remain the same as those described for the first embodiment and yield the same operation, and further explanation is thus omitted.

However, unlike the first embodiment, the drive bar 130 according to the second embodiment of the present invention is directly mounted to a drive unit 150 installed on the support 110.

In the embodiment, the guide member 140 is connected to the panel tilting shaft 125. However, it should be understood that the guide member 140 may be mounted to the solar battery panel 120 or to a panel support bar 122 supporting the panel.

The above-mentioned upward/downward rotating drive mechanism for the solar battery panel 120 according to the second embodiment almost remains the same as or is almost similar to that of the first embodiment.

However, in the second embodiment, the support 110 is configured such that part of the support 110 can be rotated to realize the biaxial drive mechanism.

Described in detail, as shown in FIG. 16, the support 110 comprises an upper support 112 and a lower support 111. The upper support 112 is fitted into the lower support 111 such that the upper support 112 can be rotatable relative to the lower support 111. Thus, the panel tilting shaft 125, the solar battery panel 120, the guide member 140 and the drive bar 130 installed on the upper support 112 form a set, which can be rotated around the lower support 111 along with the upper support 112.

The solar tracking drive mechanism using the rotating method based on the support 110 may be realized using a variety of conventional structures. In the embodiment shown in the drawings, a fixed gear 154 is mounted to the lower support 111 and a drive gear (not shown) is mounted to the upper support 112 such that the drive gear is engaged with the fixed gear. When the drive motor 155 is operated, the drive gear is rotated along the teeth of the fixed gear, so that both the upper support 112 and the structure connected to the upper support can be rotated.

In the drawings, a drive bracket 151 is provided on the upper support 112 for installing the drive unit 155 thereon. A motor 155 for rotating the drive gear and another motor 156 for rotating the drive bar 130 are installed on the drive bracket 151.

The location of the motor 156 rotating the drive bar 130, the location of the motor 155 rotating the drive gear and the structure for installing the power transmission mechanism (including a reducer) may be freely changed according to practical conditions and further explanation is omitted.

In the above-mentioned solar tracking system according to the second embodiment of the present invention, the upward and downward tilting of the solar battery panel 120 will be realized in the same manner as that described for the first embodiment. That is, the drive bar 130 is rotated by the drive power of the drive motor 156 and, in the above state, the guide member 140 is rotated along with the panel tilting shaft 125, thus tilting the solar battery panel 120 and allowing the panel to track the position of the sun according to the variations in the solar altitude (or the variations in the solar azimuth angle).

The tilting of the solar battery panel 120 around the support will be realized as follows. When the drive motor 155 is rotated, the upper support 112 is rotated around the central axis of the lower support 111. In the above state, the panel tilting shaft 125, the guide member 140 and the drive bar 130 mounted to the upper support 112 are rotated at the same time, so that the solar battery panel 120 can track the position of the sun according to the variation in the solar azimuth angle (or the variation of the solar altitude).

In FIGS. 16 through 18, reference numeral 111a denotes a support structure which is mounted to the lower support 111 and supports the upper support 112, reference numeral 112a denotes a support structure which is mounted to the upper support 112 and supports the panel tilting shaft 125, and reference numeral 135 denotes a roller bracket which is mounted to the drive bar 130 and supports the roller.

The above-mentioned biaxial solar tracking system according to the present invention uses the drive bar 130 executing the lever action and easily and reliably tilts the solar battery panels 120 upwards and downwards using relatively low amount of drive power. Further, when the solar battery panel 120 is tilted at an angle, the drive bar forms a triangular structure and stably supports the solar battery panel 120.

Hereinbelow, a third embodiment of the present invention will be described with reference with FIGS. 19 through 24.

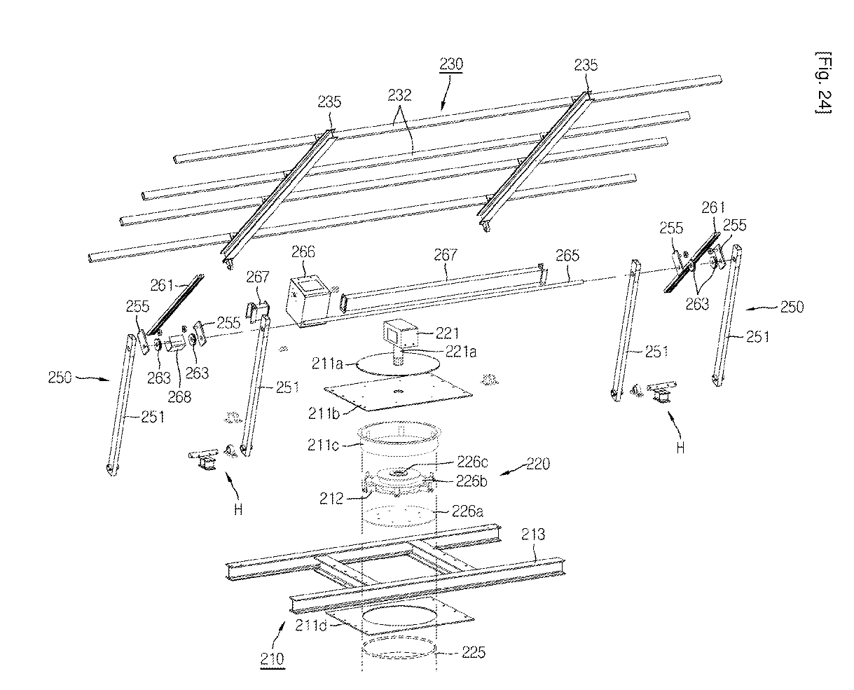

FIGS. 19 through 24 are views illustrating a solar tracking system according to the third embodiment of the present invention, in which: FIG. 19 is a side view, FIG. 20 is a rear view, FIG. 21 is a rear perspective view, FIG. 22 is a plan view, FIG. 23 is a top perspective view, and FIG. 24 is an exploded perspective view.

As shown in the drawings, the solar tracking system according to the third embodiment of the present invention comprises a horizontal support 210, a panel frame 230, a support unit 250, which are arranged to form a triangular arrangement, with a drive unit 260 provided for moving the support unit 250 relative to the panel frame 230.

The construction of the third embodiment of the present invention will be described in detail hereinbelow.

At first, a horizontal plate 211 is provided in the center of the horizontal support 210 and a pair of longitudinal supports 213 are mounted to the front and back edges of the horizontal plate 211 such that the two supports 213 extend horizontally parallel to each other.

A horizontal rotating mechanism 220, which can rotate the horizontal support 210, the panel frame 230 and the support unit 250 and tracks the position of the sun according to the variations in the solar azimuth angle, is installed on the horizontal plate 211. The horizontal rotating mechanism 220 will be described in detail later herein.

The panel frame 230 is rotatably mounted to opposite ends of the front one of the two supports 213 using hinge units H, while the support unit 250 is rotatably mounted to opposite ends of the rear support 213 using hinge units H.

In the present invention, the structure of the horizontal support 210 is not limited to that shown in the drawings, but may be freely changed to a variety of structures when an altered structure can effectively support both the panel frame 230 and the support unit 250.

The panel frame 230 is configured such that it can support solar batteries or a battery support panel 231 (hereinbelow, referred to “solar battery panel”) thereon. The panel frame 230 is rotatably connected to the horizontal support 210 such that the panel frame 230 can be tilted forwards and backwards.

In the third embodiment, the panel frame 230 comprises a plurality of horizontal frames 232 and a pair of guide frames 235. The guide frames 235 are arranged in directions perpendicular to the horizontal frames 232.

Here, the number of horizontal frames 232 and the interval between the horizontal frames 232 are determined such that the solar battery panels 231 can be stably supported on the horizontal frames 232.

The guide frames 235 transversely extend parallel to each other in the panel frame 230 at locations around opposite side portions of the panel frame 230 such that the guide frames 235 can stably support the solar battery panels. The lower ends of the guide frames 235 are rotatably mounted to opposite ends of the front support 213 of the horizontal support 210 using the hinge units H.

Particularly, the support unit 250 is slidably mounted to the guide frames 235 such that the support unit 250 can slide along the guide frames 235. Each of the guide frames 235 is provided with grooved guide rails 236 on opposite side surfaces thereof such that a roller 253 of the support unit 250 is movably engaged with the guide rails 236. Further, in back of each guide frame 235, a rack 261 constituting the drive unit 260 extends parallel to the guide frame 235.

Here, the rack 261 provided on each guide frame 235 may comprise one or two racks. In the drawings, two racks axially extend in back of each guide frame 235. Further, the location of the rack 261 is determined according to a desired rotating angle of the horizontal frame 232. In the embodiment, the rack 261 is arranged in back of only the upper portion of each guide frame 235.

The upper end of the support unit 250 is slidably engaged with the guide frames 235 of the panel frame 230, while the lower end of the support unit 250 is rotatably mounted to the horizontal support 210 using the hinge units H, so that the support unit 250 can tilt the panel frame 230 forwards and backwards according to a variation in the slidable position thereof.

The support unit 250 comprises two sets of long support bars 251, in which each set of support bars is arranged corresponding to each guide frame 235. Further, a roller 253 is provided in a junction in which each set of support bars 251 is coupled to the guide frame 235. The roller 253 is movably engaged with the guide rail 236 such that the roller 253 can slide along the guide rail 236.

As shown in FIG. 22, the roller 253 is rotatably connected to the support bar 251 using a roller bar 255. In the above state, the roller bar 255 is rotatably connected to the support bar 251, thus realizing smooth relative movement between the support bar 251 and the guide frame 235.

In the present invention, it is preferred that the roller 253 comprise two rollers engaging with opposite side surfaces of each guide frame 235.

Although the long support bars 251 are proposed as the support unit 250 in the embodiment of the present invention, it should be understood that the support unit may be configured in the form of a plate structure and may be installed between the horizontal support 210 and the panel frame 230, without limiting the structure thereof to the illustrated structure.

The drive unit 260 comprises a rack 261 provided on the guide frame 235, a pinion 263 provided on the support bar 251 of the support unit 250 and engaged with the rack 261, and a drive motor 266 installed on the support unit 250 and rotating the pinion 263.

To achieve stable engagement and reliable operation of the rack 261 and the pinion 263, it is preferred that two racks and two pinions be installed in the drive unit to form a set, as shown in FIGS. 22 and 23. Here, the two pinions 263 are preferably installed between each set of support bars 251.

A square box-shaped shaft housing 267 extends in a horizontal direction between the two sets of support bars 251. The drive motor 266 may be securely mounted to an end of the shaft housing 267. Further, a drive shaft 265 for transmitting the rotating force of the drive motor 266 to the two sets of pinions 263 may be provided inside the shaft housing 267.

Here, the location of the drive motor 266 may be freely changed. For example, when the drive motor 266 is installed at a location near the guide frame 235, the drive motor and the pinion may be arranged such that the output shaft of the drive motor is perpendicular to the shaft of the pinion, with a worm gear type power transmission mechanism provided in the junction between the two shafts to transmit power. Further, the present invention may use a screw jack type drive mechanism instead of the sliding mechanism using the rack and pinion. To realize the screw jack type drive mechanism, both a drive motor and a screw shaft are installed at locations near the guide frame, while teeth movably engaged with the screw shaft are provided at a location near the support bar, thus allowing the support bar to slide relative to the guide frame.

In the present invention, it is possible to provide another mechanism for realizing the sliding action of the support bar using both a variety of drive mechanisms and a variety of power transmission mechanisms in addition to the above-mentioned mechanisms.

Further, a pinion cap 268 for protecting the pinion 263 may be installed between the two support bars 251. In the above state, the pinion cap 268 may be configured such that it can be operated in conjunction with the roller bar 255, thus avoiding interference between the pinion cap 268 and the rack 261. The above-mentioned structure can be realized by a structure, in which two roller bars 255 are inserted into opposite side portions of the U-shaped pinion cap 268, as shown in FIG. 24.

When the drive motor 266 in the solar tracking system of the present invention is operated in a state in which the horizontal support 210, the panel frame 230 and the support units 250 are arranged in the triangular arrangement, the pinion 263 moves along the rack 261 upwards and downwards. In the above state, the support unit 250 moves along the guide frames 235 upwards and downwards, and tilts the panel frame 230 forwards and rearwards around the hinge units H of the horizontal support 210, thus tracking the variation in the solar altitude.

Further, the solar tracking system of the present invention may be configured such that it can track the position of the sun according to variations in the solar azimuth angle. This function can be achieved by the horizontal rotating mechanism 220.

The horizontal rotating mechanism 220 is configured to rotate the horizontal support 210 relative to a vertical support 225 which is placed at a specified location. As shown in FIG. 24, the horizontal rotating mechanism 220 may comprise a drive motor 221, which can rotate the horizontal plate 211 of the horizontal support 210 around the vertical support 225. Thus, when the drive motor 221 is operated, both the horizontal plate 211 and the horizontal support 210 are rotated so as to rotate all of the units provided thereon, thus tilting the solar battery panel 231 so as to track the position of the sun according to variations in the solar azimuth angle.

Hereinbelow, the above-mentioned structure will be described in detail with reference to FIG. 24. As shown in the drawing, the horizontal plate 211 of the horizontal support 210 comprises a circular plate 211a, a square plate 211b, a cylindrical body 211c and another square plate 211d, which are sequentially arranged in a direction from the top to the bottom at a location between a pair of supports 213. A drive motor 221 is securely mounted to the upper surface of the circular plate 211a. Further, rollers 212 rolling on the upper surface of a fixed circular plate 226a may be installed inside the cylindrical body 211c which will be described later herein.

To realize the above-mentioned rotatable structure, the fixed circular plate 226a is provided on the vertical support 225 and a cylindrical assembly 226b is securely mounted on the fixed circular plate 226a. Further, a bearing 226c is provided on the cylindrical assembly 226b and realizes relative movement between the square plate 211b and the cylindrical assembly 226c. Particularly, the shaft 221a of the drive motor 221 is connected to the center of the cylindrical assembly 226b.

When the drive motor 221 is rotated, the horizontal plates 211 (211a, 211b, 211c, 211d) and the support 213 are rotated along with the rotation of the drive motor 221 due to the shaft 221a of the drive motor 221 fixed to the cylindrical assembly 226b, so that the upper structure provided on the rotatable structure can be rotated.

Hereinbelow, a fourth embodiment according to the present invention will be described with reference to FIGS. 25 through 30.

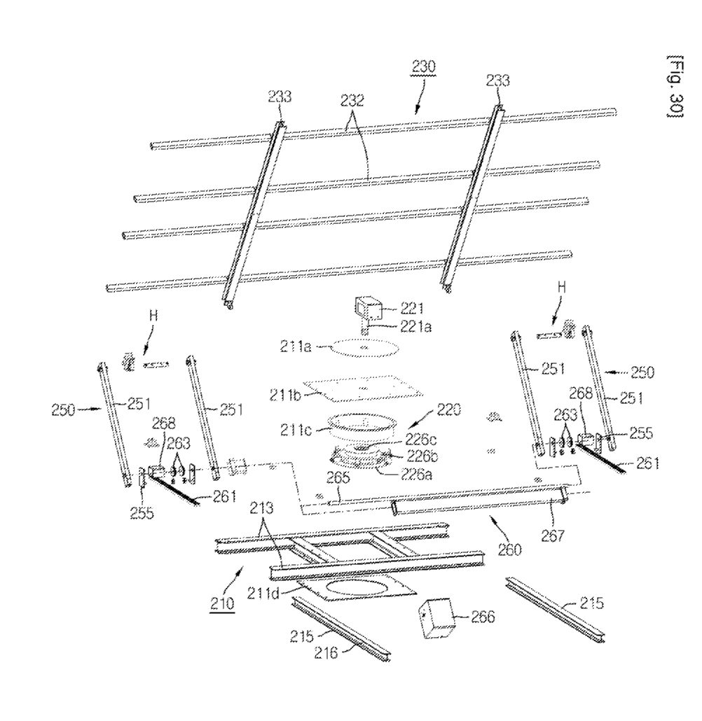

FIGS. 25 through 30 are views illustrating a solar tracking system according to the fourth embodiment of the present invention, in which: FIG. 25 is a side view, FIG. 26 is a front perspective view, FIG. 9 is a rear perspective view, FIG. 10 is a rear view, FIG. 29 is a plan view, and FIG. 30 is an exploded perspective view. In the drawings, the elements common to both the third embodiment and the fourth embodiment will use the same reference numerals.

As shown in the drawings, the solar tracking system according to the fourth embodiment of the present invention comprises a horizontal support 210, a panel frame 230 and a support unit 250, which are arranged to form a triangular arrangement, in the same manner as that described for the third embodiment of the present invention.

Unlike the third embodiment, the support unit 250 according to the fourth embodiment of the present invention is slidably coupled to the horizontal support 210.

In other words, the upper end of the support unit 250 is rotatably mounted to the panel frame 230 using a hinge unit H, while the lower end of the support unit 250 is rotatably mounted to the horizontal support 210.

To realize the above-mentioned structure, the panel frame 230 is provided with a vertical frame 233 which crosses the horizontal frame 232. The vertical frame 233 is coupled to the horizontal support 210 at the lower end thereof using a hinge unit H and is coupled to the support unit 250 at the middle portion thereof using a hinge unit H.

Particularly, the horizontal support 210 is provided with both a horizontal plate 211 and a pair of supports 213 in the same manner as that described for the third embodiment. Guide frames 215 are mounted to opposite ends of the pair of supports 213, so that the guide frames 215 extend in parallel to each other.

Each of the guide frames 215 is provided with guide rails 216 on opposite side surfaces in the same manner as that described for the guide frame 235 of the third embodiment. Further, a rack 261 is provided along the upper surface of each guide frame 215.

The support unit 250 is configured such that it slides forwards and backwards along the upper surface of the guide frame 215 and allows the solar battery panel 231 to be tilted to track variations in the solar altitude. In the same manner as that described for the third embodiment, a pair of rollers 253 supported by roller bars 255 are provided on ends of a pair of support bars 251 and a pinion 263 is placed between the support bars 251.

Further, a shaft housing 267 is connected to the two sets of support bars 251 at a location between the two sets of support bars 251. The shaft housing 267 is provided with a drive motor 266 and a drive shaft 265, which transmits the rotating force of the drive motor 266 to the pinion 263.

In the embodiment, the drive motor 266 may be installed at a location near the guide frame 215 or a location near the horizontal support 210. Further, the sliding movement of the support bar 251 relative to the guide frame 215 may be realized using a ball screw type mechanism instead of the rack and pinion mechanism. Both the drive mechanism and the power transmission mechanism adapted in the fourth embodiment may remain the same as those of the third embodiment and further explanation is thus omitted.

Unlike the third embodiment, the support unit 250 according to the fourth embodiment of the present invention is slidably mounted to the horizontal support 210 and the drive unit 260 for moving the support unit 250 is located at a junction between the support unit 250 and the horizontal support 210.

In the fourth embodiment, elements other than those of the above-mentioned construction remain the same as those of the third embodiment and further explanation is thus omitted.

Hereinbelow, a fifth embodiment of the present invention will be described with reference to FIGS. 31 and 32.

FIGS. 31 and 32 are views illustrating a solar tracking system according to the fifth embodiment of the present invention, in which: FIG. 31 is a perspective view and FIG. 32 is an exploded perspective view illustrating important parts of FIG. 31. In the drawings, the elements common to both the fifth embodiment and the first through fourth embodiments will carry the same reference numerals and further explanation thereof is omitted.

In the fifth embodiment of the present invention, a horizontal rotating mechanism 270 fabricated using a cam mechanism is proposed unlike the horizontal rotating mechanisms 220 proposed in the first through fourth embodiments.

As shown in the drawings, the horizontal rotating mechanism 270 according to the fifth embodiment is installed in the lower part of the solar tracking system having the construction similar to that described in the fourth embodiment. The horizontal rotating mechanism 270 comprises an upper column 217 mounted to the horizontal support 210A and a lower column 227 constituting the vertical support 225A. The upper column 217 is rotatably fitted over an inner cylinder 228 of the lower column 227. Further, a rotation drive unit 280 is installed between the upper column 217 and the lower column 227 and rotates the upper column 217 relative to the lower column 227.

Here, the rotation drive unit 280 comprises a plurality of protrusions 281 and a cam gear 285. The protrusions 281 are formed on the lower surface of a flange 229 provided in the lower column 227 such that the protrusions 281 are circumferentially spaced apart from each other at regular intervals. The cam gear 285 is mounted to the upper column 217 and is engaged with the protrusions 281 such that, when the drive motor 283 is rotated, the cam gear 285 moves in a circumferential direction of the lower column 227 due to relative movement between the cam gear 285 and the protrusions 281, thus rotating the upper column 217.

In the above state, it is preferred that a bearing 287 be provided on the upper surface of the flange 229 of the lower column 227 such that, when the upper column 217 is rotated, the bearing 287 can minimize the rotating resistance. Further, it is preferred that a support plate 218 be installed on the upper column 217 for supporting the cam gear 285 and the drive motor 266.

It is also preferred that the cam gear 285 be connected to a cam shaft 286 and be installed in a cam housing 288. The cam housing 288 is securely mounted to the support plate 218. The drive motor 266 driving the cam gear 285 may be directly connected to the cam shaft 286 or may be indirectly connected to the cam shaft 286 through a reducer gear box 289, as shown in the drawings.

The cam gear 285 is provided with a spiral cam surface 285a. Further, the cam shaft 286 is horizontally arranged such that the spiral cam surface 285a is movably engaged with the vertical protrusions 281.

Therefore, when both the cam shaft 286 and the cam gear 285 are rotated by the drive motor 283, the spiral cam surface 285a of the cam gear 285 is rotated relative to the protrusions 281 of the flange 229. Thus, the upper column 217, to which the cam gear 285 is fixed, is rotated relative to the lower column 227. Therefore, the horizontal support 210A, the panel frame 230 and the support unit 250, which are combined with the upper column 217, are rotated, so that the solar tracking system can track the position of the sun according to variations in the solar azimuth angle.

In the above description, the horizontal rotating mechanism 270 is configured such that the upper column 217 is fitted over the lower column 227. However, the structure of the horizontal rotating mechanism 270 is not limited to the above-mentioned structure, but may be changed to another structure in which the upper column 217 is fitted into the lower column 227. Further, the protrusions 281 of the flange 287 may be integrated with the upper column 217, while the cam gear 285, which is movably engaged with the protrusions 281, may be fixedly mounted to the lower column 227.

Hereinbelow, another embodiment of the horizontal rotating mechanism according to the present invention will described with reference to FIG. 33.

FIG. 33 is a perspective view illustrating the construction of important parts of a horizontal rotating mechanism according to another embodiment of the present invention.

FIG. 33 illustrates the horizontal rotating mechanism 310, based on a rotation drive unit 370 included in the mechanism 310. The construction of the rotation drive unit 370 shown in FIG. 33 may be adapted to the horizontal rotating mechanisms according to the second through fifth embodiments of the present invention.

In other words, the horizontal rotating mechanism 310 according to this embodiment is assembled with a panel frame and a structure supporting the panel frame, which are the same as those described in the second through fifth embodiments. In the above state, the structure supporting the panel frame may comprise a horizontal support 110 or 210, a support unit 150 or 250 and a drive unit 160 or 260, as shown in FIG. 10, FIG. 19, FIG. 25 and FIG. 31.

The horizontal rotating mechanism 310 is configured such that it can horizontally rotate the above-mentioned panel frame 130 or 230, the horizontal support 110 or 210, the support unit 150 or 250 and the drive unit 160 or 260 (hereinbelow, referred to as “upper structure”). The horizontal rotating mechanism 310 is provided between the upper structure and a vertical support 325, which supports the upper structure in a vertical direction.

In the horizontal rotating mechanism 310, the lower end of the upper structure is rotatably mounted to the vertical support 325. At the junction between the upper structure and the vertical support 325, a rotation drive unit 370 is installed to allow the upper structure to be rotated relative to the vertical support 325.

FIG. 33 illustrates the horizontal rotating mechanism 310 but does not show the upper structure. In the drawing, reference numeral 315 denotes a central shaft to which the upper structure is mounted. The upper structure may be supported on the center of the upper surface of the vertical support 325 using a bearing.

The vertical support 325 may be the lower column 227 shown in FIG. 32. Reference numeral 326 denotes an upper edge of the vertical support 325, on which a thrust bearing may be installed to rotatably support the upper structure on the vertical support 325. For example, the upper column of FIG. 32 may be supported on the vertical support 325 using a bearing such that the upper column can be smoothly rotated in a state in which the upper column is placed on the vertical support 325.

Hereinbelow, the rotation drive unit 370 will be described.

The rotation drive unit 370 comprises a driven gear 381 and a drive body 385. The driven gear 381 is formed around the circumference of the vertical support 325. The drive body 385 comprises a plurality of engaging rods 386, which are arranged at regular intervals in a circumferential direction and are movably engaged with the teeth of the driven gear 381. The drive body 385 is rotated by the rotating force of the drive motor 383 and rolls along the circumference of the driven gear 381, thus rotating the upper structure. In the above state, the drive body 385 and the drive motor 383 are mounted in the upper structure.

The drive body 385 preferably comprises the engaging rods 386 and drive discs 387. The engaging rods 386 are circumferentially arranged at regular intervals between the drive discs 387 and are movably engaged with the driven gear 381. The drive discs 387 are circular discs and hold the upper and lower ends of the engaging rods 386, with the output shaft 384 of the drive motor 383 connected to the drive discs 387, thus rotating the drive body 385.

Here, bearing members 388 are provided between the drive discs 387 and the engaging rods 386, so that, when the engaging rods 386 are engaged with and disengaged from the teeth of the driven gear 381, the engaging rods 386 can roll relative to the driven gear 381, thus minimizing the slip resistance and providing a desired rotating force.

In the drawing, the upper structure supporting both the drive motor 383 and the drive body 385 is not shown. However, a support structure, such as a bracket, for supporting the drive motor 383 and the drive body 385 to the upper structure is well known to those skilled in the art, so that the support structure is omitted from the drawing.

Further, in the drawing, the driven gear 381 is provided on the vertical support 325 which is a lower structure and the drive body 385 is provided in the upper structure. However, it should be understood that the driven gear 381 may be provided on the upper structure and both the drive body 385 and the drive motor 383 may be mounted to the vertical support 325, when necessary.

In the above description of the embodiments, the present invention is adapted to a solar tracking system, in which the solar battery panel is arranged in the form of a flat panel structure. However, it should be understood that the present invention may be freely adapted to a variety of solar systems which are configured to collect and use solar rays or solar heat, such as a solar ray collecting system configured to collect solar rays using a reflective panel, without being limited to the description.

1. A solar tracking system, comprising:
a vertical support;
a solar battery panel rotatably mounted to an upper end of the vertical support;
a drive bar rotatably mounted to an intermediate portion of the support;
a guide member rotatably mounted to the upper end of the support and rotated by the drive bar, thus tilting the solar battery panel; and
a drive unit rotating the drive bar,
wherein the drive bar is connected to the guide member such that the drive bar can be linearly moved along the guide member.

2. The solar tracking system according to claim 1, wherein a panel tilting shaft is mounted to the upper end of the support such that the panel tilting shaft extends horizontally, and
the solar battery panel and the guide member are mounted to the panel tilting shaft such that the solar battery panel and the guide member can be rotated simultaneously.

3. The solar tracking system according to claim 1, wherein the support, the solar battery panel, the drive bar and the guide member form a basic set,
a plurality of basic sets are sequentially arranged, and
the drive unit synchronously drives the solar battery panels provided in the plurality of basic sets.

4. The solar tracking system according to claim 3, wherein the drive unit comprises a drive motor, a drive shaft for transmitting a rotating force of the drive motor to the drive bars of the basic sets, and a power transmission mechanism provided between the drive shaft and the drive bars.

5. The solar tracking system according to claim 1, wherein the drive unit is a drive motor directly installed on the support and rotating the drive bar.

6. The solar tracking system according to claim 1, wherein the support rotates the solar battery panel, the drive bar and the guide member therearound.

7. A solar tracking system, comprising:
a horizontal support;
a panel frame connected to the horizontal support such that the panel frame can be tilted forwards and backwards, with a solar battery installed on the panel frame;
a support unit connected both to the horizontal support and to the panel frame such that the support unit in cooperation with the horizontal support and the panel frame forms a triangular arrangement, wherein the support unit is slidably connected to either the horizontal support or the panel frame such that the support unit can slide relative to either the horizontal support or to the panel frame, thus tilting the panel frame forwards and backwards according to variations in a slidable position thereof; and
a drive unit for sliding the support unit relative to the horizontal support or the panel frame.

8. The solar tracking system according to claim 7, wherein the support unit is slidably connected to the panel frame at an upper end thereof and is rotatably connected to the horizontal support at a lower end thereof.

9. The solar tracking system according to claim 8, wherein the panel frame is provided with a transversely extending guide frame to which the support unit is slidably connected, and
the guide frame is rotatably connected to the horizontal support at a lower end thereof.

10. The solar tracking system according to claim 9, wherein the drive unit comprises: a rack provided on the guide frame, a pinion provided on the support unit and engaged with the rack, and a drive motor provided on the support unit and rotating the pinion.

11. The solar tracking system according to claim 7, wherein the support unit is rotatably connected to the panel frame at an upper end thereof and is slidably connected to the horizontal support at a lower end thereof.

12. The solar tracking system according to claim 11, wherein the horizontal support is provided with a transversely extending guide frame to which the support unit is slidably connected, and
the panel frame is rotatably connected to an end of the guide frame.

13. The solar tracking system according to claim 12, wherein the drive unit comprises: a rack provided on the guide frame, a pinion provided on the support unit and engaged with the rack, and a drive motor provided on the support unit and rotating the pinion.

14. The solar tracking system according to claim 10, wherein the support unit comprises two pairs of parallel support bars, with the pinion located between each pair of support bars,
a shaft housing is connected to the two pairs of support bars, and
the shaft housing is provided with both the drive motor and a drive shaft for transmitting a rotating force of the drive motor to the pinion.

15. The solar tracking system according to claim 7, wherein the horizontal support is rotatably installed on a vertical support using a horizontal rotating mechanism.

16. The solar tracking system according to claim 15, wherein the horizontal rotating mechanism comprises an upper column mounted to the horizontal support and a lower column constituting the vertical support, wherein one of the upper and lower columns is rotatably fitted into a remaining column, and
a rotation drive unit is provided between the upper column and the lower column and rotates the upper column relative to the lower column.

17. The solar tracking system according to claim 16, wherein the rotation drive unit comprises: a plurality of protrusions formed on a lower surface of a flange provided in the lower column such that the protrusions are circumferentially spaced apart from each other at regular intervals; and a cam gear mounted to the upper column and engaged with the protrusions such that, when the drive motor is rotated, the cam gear moves in a circumferential direction of the lower column due to relative movement between the cam gear and the protrusions, thus rotating the upper column.

18. The solar tracking system according to claim 16, wherein the rotation drive unit comprises: a plurality of protrusions formed on an upper or lower surface of a flange provided in the upper or lower column such that the protrusions are circumferentially spaced apart from each other at regular intervals; and a cam gear mounted to a remaining column and engaged with the protrusions such that, when the drive motor is rotated, the cam gear moves in a circumferential direction of the lower column due to relative movement between the cam gear and the protrusions, thus rotating the upper column.

19. The solar tracking system according to claim 15, wherein the horizontal rotating mechanism rotatably supports the upper structure on the vertical support, and comprises a rotation drive unit installed between the upper structure and the vertical support and rotating the upper structure relative to the vertical support, wherein the rotation drive unit comprises: a driven gear formed around the vertical support; and a drive body mounted to the upper structure and having a plurality of engaging rods circumferentially arranged in the drive body and engaged with the driven gear, thus being rotated around the driven gear by a rotating force of the drive motor mounted to the upper structure and thereby rotating the upper structure including the panel frame.
